(19) United States
(12) Patent Application Publication
(10) Pub. No.: US 2002/0112667 A1
(43) Pub. Date: Aug. 22, 2002

(54) Vacuum apparatus of ion implantation system and evacuation method

(75) Inventor: Hyo-Sang Jung, Suwon-city (KR)

Correspondence Address: The Law Offices of Eugene M Lee, PLLC, 1101 Wilson Boulevard, Suite 2000, Arlington, VA, 22209, US

(73) Assignee: Samsung Electronics Co., Ltd.

(21) Appl. No.: 10/068,005

(22) Filed: Feb. 8, 2002

(30) Foreign Application Priority Data
Feb. 19, 2001 (KR) 2001-8175

(51) Int. Cl. C23C 16/00

(52) U.S. Cl. 118/723 FI

(57) ABSTRACT

A vacuum apparatus of an ion implantation system having an ion generator includes a vacuum pump evacuating the interior of the ion generator, a vacuum line connected between the vacuum pump and the ion generator, at least one first type valve connected to the ion generator and the vacuum line for injecting an inert gas into the ion generator and the vacuum line to equalize internal and external pressures of the ion generator and the vacuum line and to remove the air from the interior of the ion generator and the vacuum line, so that oxygen does not react with an inflammable impurity inside the ion generator, and at least one second type valve connected to the ion generator for being closed or opened to maintain a pressure of the ion generator to a predetermined vacuum level.

### BACKGROUND OF THE INVENTION

1. Field of the Invention

The present invention relates to an ion implantation system. More particularly, the present invention relates to a vacuum apparatus of an ion implantation system that can safely evacuate an interior of an ion generator.

2. Description of the Related Art

An ion implantation system includes an ion generator and a vacuum apparatus. The ion generator includes an ion source and a charge converter. The ion generator generates a cation beam when a high electric field is applied to the ion source and a gas, such as BF₃, PH₃ and AsH₃, flows thereinto. The charge converter is filled with a vapor that is produced when magnesium is heated and then sublimated, and converts the cation beam generated by the ion source into an anion beam. While passing through the charge converter, the cation beam interacts with the magnesium vapor and receives electrons to be converted into an anion beam. The ion generator operates in a vacuum atmosphere and thus requires a vacuum apparatus to maintain a vacuum atmosphere inside the ion generator.

While evacuating the air from the ion generator in order to obtain a low vacuum pressure inside the ion generator, the vacuum line of the vacuum apparatus is contaminated by inflammable impurities such as phosphorous, hydrogen and magnesium. Therefore, a need exists for cleaning the interior of the ion generator and replacing damaged parts.

In order to clean the interior of the ion generator and replace damaged parts, the ion generator must be opened. After cleaning the interior of the ion generator or replacing the damaged parts, the ion generator is reassembled.

While the ion generator is opened, however, oxygen flows into the ion generator and the vacuum line. After reassembly, when the vacuum apparatus performs a pumping operation in order to maintain a vacuum atmosphere inside the ion generator, oxygen present in the ion generator and the vacuum line may react with inflammable impurities deposited in the vacuum line and may cause an explosion.

### SUMMARY OF THE INVENTION

To overcome the problems described above, preferred embodiments of the present invention provide a vacuum apparatus that may safely evacuate the interior of an ion generator and the vacuum line.

It is another feature of an embodiment of the present invention to provide a method of safely evacuating an ion generator and vacuum line.

The preferred embodiments of the present invention provide a vacuum apparatus of an ion implantation system having an ion generator. The vacuum apparatus includes a vacuum pump for evacuating the interior of the ion generator, a vacuum line connected between the vacuum pump and the ion generator, at least one first type valve connected to the ion generator and the vacuum line for injecting an inert gas into the ion generator and the vacuum line to equalize internal and external pressures of the ion generator and the vacuum line and also to remove the air from the interior of the ion generator and the vacuum line, so that oxygen does not react with an inflammable impurity inside the ion generator and the vacuum line, and at least one second type valve connected to the ion generator for being closed or opened to maintain the pressure of the ion generator to a predetermined vacuum level.

Preferably, the first type valve is a solenoid valve. Also preferably, the inert gas is an argon gas or a nitrogen gas. The inflammable impurity includes phosphorous, hydrogen and magnesium. The vacuum pump preferably includes a turbo pump and a roughing pump. Regarding the at least one first type valve, one valve is directly connected to the ion generator, and others may be arranged at locations adjacent to the vacuum pump. Regarding the at least one second type valve, one valve is directly connected to the ion generator, and others may be arranged at locations adjacent to the vacuum pump.

A preferred embodiment of the present invention further provides an evacuation method in an ion implantation system including an ion generator and a vacuum apparatus including a vacuum line. The method includes injecting an inert gas into an interior of the ion generator and the vacuum line to equalize internal and external pressures of the ion generator and the vacuum line; opening the ion generator to clean the inside thereof or to replace a damaged part; closing the ion generator; and injecting the inert gas into the interior of the ion generator and the vacuum line to remove the air from the interior of the ion generator and the vacuum line, so that oxygen does not react with an inflammable impurity inside the ion generator and the vacuum line. In this evacuation method the inert gas may be an argon gas or a nitrogen gas and the inflammable impurity may include phosphorus, hydrogen, and magnesium.

These and other features of the present invention will be readily apparent to those of ordinary skill in the art upon review of the detailed description that follows.

### BRIEF DESCRIPTION OF THE DRAWINGS

For a more complete understanding of the present invention and the advantages thereof, reference is now made to the following descriptions taken in conjunction with the accompanying drawings, in which like reference numerals denote like elements throughout, and in which:

FIG. 1 is a schematic diagram illustrating a conventional ion implantation system according to the prior art;

FIG. 2 is a flow chart illustrating a conventional process of cleaning an ion generator and replacing a damaged part of the ion generator according to the prior art;

FIG. 3 is a schematic diagram illustrating an ion implantation system according to a preferred embodiment of the present invention; and

FIG. 4 is a flow chart illustrating a method of safely evacuating an ion generator according to a preferred embodiment of the present invention.

### DETAILED DESCRIPTION OF THE INVENTION

Korean Patent Application No. 2001-8175, filed on Feb. 19, 2001, and entitled: “Vacuum Apparatus of Ion Implantation System and Vacuumizing Method,” is incorporated by reference herein in its entirety.

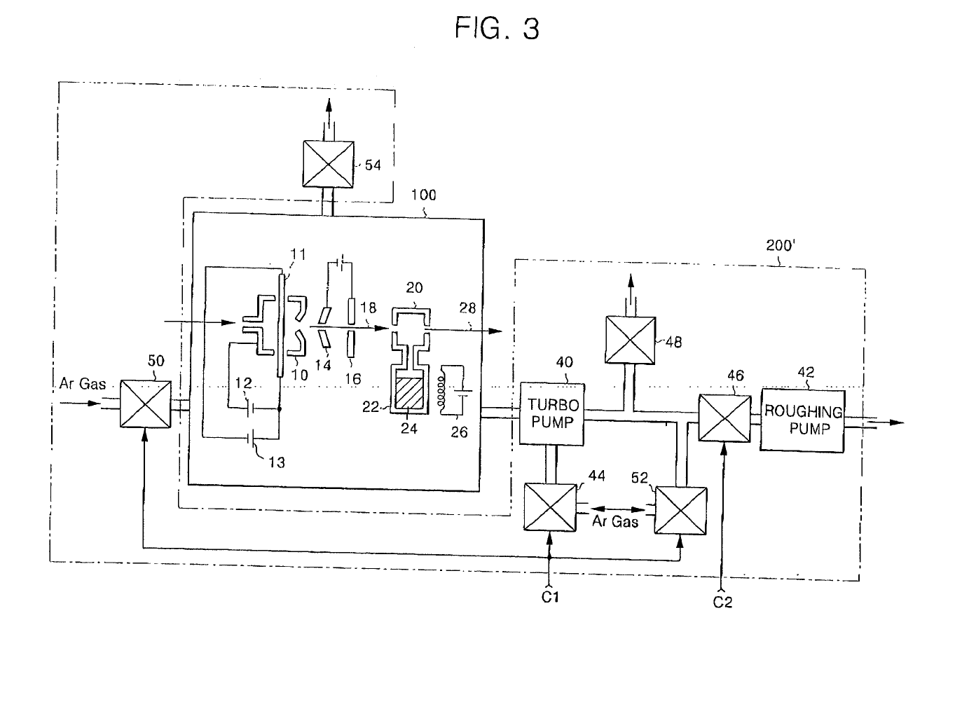

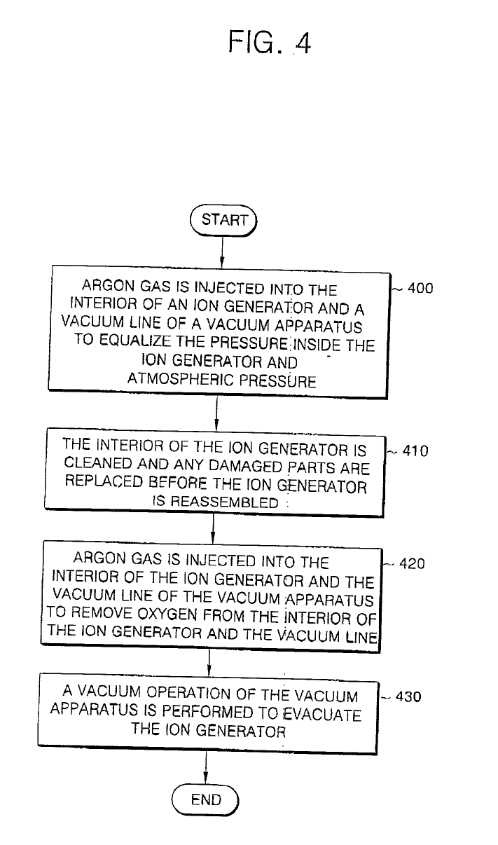

Detailed reference will now be made to preferred embodiments of the present invention, an example of which is illustrated in FIGS. 3 and 4 of the accompanying drawings.

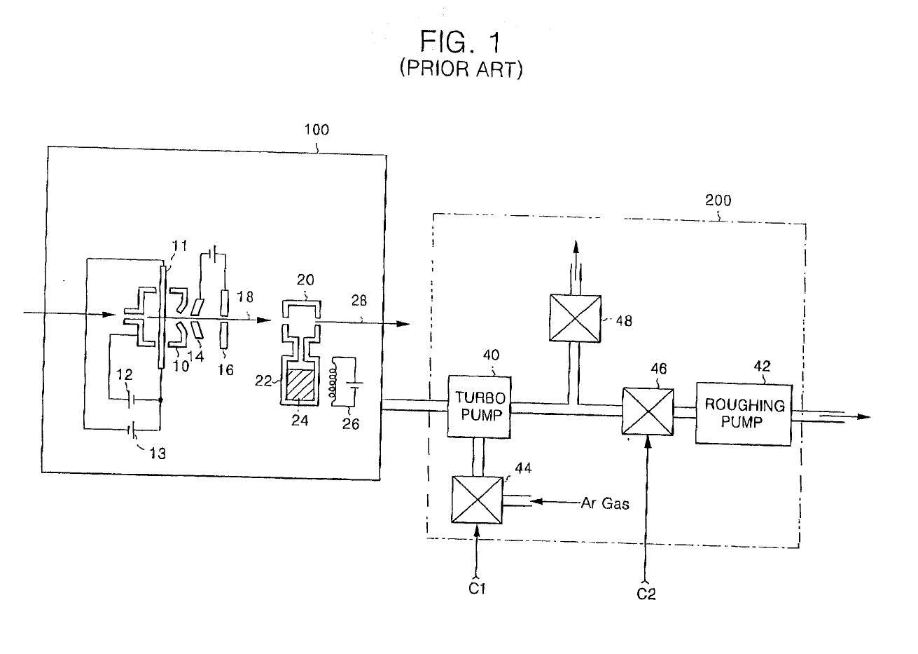

Turning now to FIG. 1, a conventional ion implantation system includes an ion generator 100 and a vacuum apparatus 200. The ion generator 100 includes an arc chamber 10, a filament 11, an arc voltage source 12, a filament heating source 13, a suppress electrode 14, a plug electrode 16, a charge converter 20, a vapor container 22, magnesium 24, and a heater 26. The vacuum apparatus 200 includes a turbo pump 40, a roughing pump 42, a vent valve 44, a roughing valve 46, and a relief valve 48.

The charge converter 20 communicates with the vapor container 22, and the vapor container 22 is filled with vapors that are produced when magnesium is heated by the heater 26 and then sublimated. The vent valve 44 and the roughing valve 46 are solenoid valves that operate in response to control signals C1 and C2 generated from a controller (not shown).

Operation of the ion implantation system of FIG. 1 is as follows. The interior of the ion generator 100 is evacuated by the vacuum apparatus 200. The arc voltage 12 is applied to the interior of the ion generator 100, a heater operates, and a gas, such as BF₃, PH₃ and AsH₃, is injected into the interior of the arc chamber 10. The arc chamber 10 and the filament 11 are heated by the filament heating source 13 and activate an injected ion gas to generate a cation beam 18. The suppress electrode 14 and the plug electrode 16 converge the cation beam 18 to enter the charge converter 20. The charge converter 20 converts the cation beam 18 into an anion beam 28. More particularly, the cation beam 18 interacts with the magnesium vapor and receives electrons, and is then converted into an anion beam 28.

The vacuum apparatus 200 maintains a vacuum atmosphere inside the ion generator 100 while the ion generator 100 performs an operation to generate the anion beam 28. That is, during an operation of the ion generator 100 to generate the anion beam 28, the turbo pump 40 and the roughing pump 42 are turned on, the roughing valve 46 is opened in response to the control signal C2, so that a vacuum atmosphere is maintained inside the ion generator 100. The relief valve 48 is closed when the vacuum line is at a predetermined atmospheric pressure, and is automatically opened to maintain the interior of the ion generator 100 at the predetermined pressure when the pressure of the vacuum line becomes greater than the predetermined pressure.

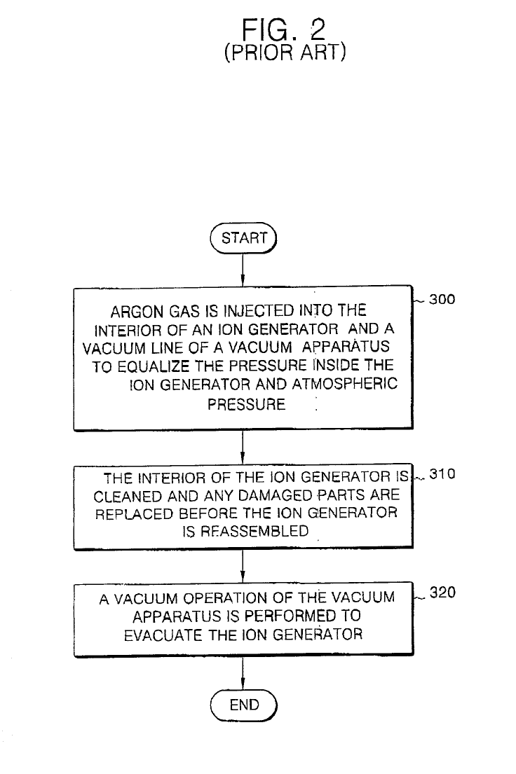

FIG. 2 is a flow chart illustrating a conventional process of cleaning the ion generator and replacing a damaged part of the ion generator according to the prior art.

The turbo pump 40 and the roughing pump 42 are turned off, and the roughing valve 46 is closed in response to the control signal C2. Then, the ion generator is opened to clean the interior of the ion generator 100 and replace any damaged parts. However, to open the ion generator, it is required that the pressure inside the ion generator be equal to atmospheric pressure. Therefore, vent valve 44 is opened in response to the control signal C1, and argon (Ar) gas is injected into both the interior of the ion generator 100 and the vacuum line of the vacuum apparatus 200 (step 300).

When the pressure inside the ion generator is equal to atmospheric pressure, vent valve 44 is closed in response to the control signal C1.

Thereafter, the ion generator 100 is opened, and the inside ambient state of the ion generator 100 becomes an atmospheric state. The interior of the ion generator 100 is cleaned and any damaged parts are replaced before the ion generator 100 is reassembled (step 310).

The turbo pump 40 and the roughing pump 42 are then turned on, and the roughing valve 46 is opened in response to the control signal C2. Thereafter, an ion generating operation of the ion generator 100 and a vacuum producing operation of the vacuum apparatus 200 are repeatedly performed (step 320). It is difficult, however, to completely clean all parts inside the ion generator 100. Accordingly, some inflammable impurities remain inside the ion generator 100.

In addition, as described above, during the cleaning of the interior of the ion generator 100 and the replacing of any damaged parts, oxygen flows into the ion generator and the vacuum line. When the roughing valve 46 is opened and the roughing pump 42 performs the pumping operation at the beginning stage to evacuate the interior of the ion generator, oxygen rapidly flows through the vacuum line, whereby oxygen reacts with the remaining inflammable impurities like phosphorus, hydrogen, and magnesium and may cause an explosion.

FIG. 3 shows an ion implantation system according to a preferred embodiment of the present invention. The ion generator 100 of FIG. 3 is similar to that of FIG. 1, and the vacuum apparatus of FIG. 3 is similar to that of FIG. 1 except for the additional vent valves 50 and 52 and a relief valve 54. Like reference numerals of FIGS. 1 and 3 denote like elements.

Similar to vent valve 44, vent valves 50 and 52 are preferably solenoid valves that operate in response to the control signal C1. Vent valve 50 and relief valve 54 control the pressure inside the ion generator 100, and the vent valve 52 controls the pressure inside the vacuum line. Vent valves 44, 50 and 52 are opened to inject argon gas into the interior of the ion generator 100 and the vacuum line of the vacuum apparatus 200′ to equalize the pressure inside the ion generator to atmospheric pressure and to rapidly remove oxygen from the inside of the ion generator 100 and the vacuum line of the vacuum apparatus 200′. This will be explained below in detail.

FIG. 4 is a flow chart illustrating a method of safely evacuating the ion generator 100 according to a preferred embodiment of the present invention.

The turbo pump 40 and the roughing pump 42 are turned off, and the roughing valve 46 is closed in response to the control signal C2. Vent valves 44, 50 and 52 are then opened in response to the control signal C1 to inject argon gas into the interior of the ion generator 100 and the vacuum line of the vacuum apparatus 200′ to equalize the pressure inside the ion generator to atmospheric pressure. When the pressure inside the ion generator is equal to atmosphere pressure, vent valves 44, 50 and 52 are closed in response to the control signal C1, and the ion generator is opened, so that the inside ambient state of the ion generator 100 becomes an atmospheric state (step 400).

Thereafter, the ion generator 100 is cleaned, and any damaged parts are replaced before reassembling the ion generator 100 (step 410). Argon gas is injected into the interior of the ion generator 100 and the vacuum line of the vacuum apparatus 200′ through vent valves 44, 50 and 52 to rapidly remove oxygen from the interior of the ion generator and the vacuum line through the relief valves 54 and 48, respectively (step 420).

Vent valves 44, 50 and 52 are then closed in response to the control signal C1, and the turbo pump 40 and the roughing pump 42 are turned on to pump the argon gas. The roughing valve 46 is opened, and then an ion generating operation of the ion generator 100 and a vacuum operation of the vacuum apparatus 200′ are repeatedly performed (step 430).

In step 430, even though the roughing valve 46 is opened and the pumping operation is performed by the roughing pump 42, since the interior of the ion generator 100 and the vacuum line of the vacuum apparatus 200′ are filled with an inert gas, i.e., argon gas or nitrogen gas, the inert gas does not react with the inflammable impurities, so that an explosion does not occur, thereby leading to a safe operation.

In a preferred embodiment of the present invention, in order to prevent an explosion from occurring due to a reaction of oxygen and an inflammable impurity, argon gas is injected through the three vent valves 44, 50 and 52. In the alternative, argon gas may be injected through only vent valve 44. That is, a method of safely evacuating the ion generator may be performed in the vacuum apparatus of FIG. 1, however, the speed at which oxygen is evacuated in that case is significantly slower than in the present invention.

As previously described herein, since oxygen present inside the ion generator 100 and the vacuum apparatus 200′ is completely evacuated before the pumping operation is performed by the roughing pump 42 an explosion due to a reaction of oxygen and an inflammable gas no longer occurs, thereby resulting in a safe operation. Typical inflammable impurities include phosphorus, hydrogen, and magnesium.

Preferred embodiments of the present invention have been disclosed herein and, although specific terms are employed, they are used in a generic and descriptive sense only and not for purpose of limitation. Accordingly, it will be understood by those of ordinary skill in the art that various changes in form and details may be made without departing from the spirit and scope of the invention as set forth in the following claims.

What is claimed is:

1. A vacuum apparatus of an ion implantation system having an ion generator, comprising:
a vacuum pump evacuating an interior of the ion generator;
a vacuum line connected between the vacuum pump and the ion generator;
at least one first type valve connected to the ion generator and the vacuum line for injecting an inert gas into the ion generator and the vacuum line to equalize internal and external pressures of the ion generator and the vacuum line and also to remove the air from the interior of the ion generator and the vacuum line, so that oxygen does not react with an inflammable impurity inside the ion generator and the vacuum line; and
at least one second type valve connected to the ion generator for being closed or opened to maintain the pressure of the ion generator to a predetermined vacuum level.

2. The apparatus as claimed in claim 1, wherein the first type valve is a solenoid valve.

3. The apparatus as claimed in claim 1, wherein the inert gas is selected from the group consisting of an argon gas and a nitrogen gas.

4. The apparatus as claimed in claim 1, wherein the inflammable impurity includes one or more of phosphorous, hydrogen and magnesium.

5. The apparatus as claimed in claim 1, wherein the vacuum pump includes a turbo pump and a roughing pump.

6. The apparatus as claimed in claim 1, wherein one of the at least one first type valve is directly connected to the ion generator, and any additional first type valves are arranged at locations adjacent to the vacuum pump.

7. The apparatus as claimed in claim 5, wherein one of the at least one second type valve is directly connected to the ion generator, and any additional second type valves are arranged at locations adjacent to the vacuum pump.

8. An evacuation method in an ion implantation system including an ion generator and a vacuum apparatus including a vacuum line, the method comprising:
injecting an inert gas into the interior of the ion generator and the vacuum line to equalize internal and external pressures of the ion generator and the vacuum line;
opening the ion generator to clean the interior thereof or to replace a damaged part;
closing the ion generator; and
injecting the inert gas into the interior of the ion generator and the vacuum line to remove the air from the inside of the ion generator and the vacuum line, so that oxygen does not react with an inflammable impurity inside the ion generator and the vacuum line.

9. The method as claimed in claim 8, wherein the inert gas is selected from the group consisting of an argon gas and a nitrogen gas.

10. The method as claimed in claim 8, wherein the inflammable impurity includes phosphorus, hydrogen and magnesium.
